(19) United States
(12) Patent Application Publication
(10) Pub. No.: US 2009/0302885 A1
(43) Pub. Date: Dec. 10, 2009

(54) TWO TRANSISTOR TIE CIRCUIT WITH BODY BIASING

(76) Inventors: JIANAN YANG, Austin, TX (US); Wang K. Chen, Austin, TX (US); Stephen G. Jamison, Austin, TX (US); Arthur R. Piejko, Austin, TX (US); Jun Tang, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/134,273

(22) Filed: Jun. 6, 2008

(51) Int. Cl. H03K 19/003; G05F 1/00

(52) U.S. Cl. 326/27; 327/537

(57) ABSTRACT

A circuit for body biasing is provided. The circuit includes: (1) a p-type transistor having a first current terminal, which is coupled to a first voltage supply, a second current terminal, a control terminal, and a bulk terminal; and (2) an n-type transistor having a first current terminal, which is coupled to a second voltage supply different from the first voltage supply, a second current terminal, a control terminal, and a bulk terminal, wherein the bulk terminal of the p-type transistor, the second current terminal of the p-type transistor, and the control terminal of the n-type transistor is coupled to a first node, wherein the control terminal of the p-type transistor, the bulk terminal of the n-type transistor, and the second current terminal of the second transistor is coupled to a second node different from the first node.

### BACKGROUND

1. Field

This disclosure relates generally to circuits, and more specifically, to two transistor tie circuits with body biasing.

2. Related Art

In many instances, logic inputs of a device cannot be directly tied to voltage supply terminals, such as VDD and ground terminals. Instead, a tie-high/tile-low circuit is inserted between the logic input and the voltage supply terminal. Such an arrangement is often necessary to protect the circuitry located on the device from electrostatic discharges. While these tie-high/tie-low circuits are effective in protecting the circuitry on the device, they create other issues. For example, traditional four transistor tie-high/tie-low circuits take up valuable space on the device. Certain tie-high/tie-low circuits use two transistors instead and thus take up less space. Such two transistor circuits, however, use complicated biasing schemes to ensure proper operation. That in turn results in wasted space and complex circuits.

Accordingly there is a need for a two transistor tie circuit with body biasing.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 shows an exemplary block diagram of a device including a tie-high/tie-low circuit;

FIG. 2 shows an exemplary circuit diagram of the tie-high/tie-low circuit of FIG. 1;

FIG. 3 shows another exemplary circuit diagram of the tie-high/tie-low circuit of FIG. 1;

FIG. 4 shows an exemplary layout for the tie-high/tie-low circuit of FIG. 2; and

FIG. 5 shows an exemplary layout for the tie-high/tie-low circuit of FIG. 3.

### DETAILED DESCRIPTION

In one aspect, a circuit, which may be used for body biasing is provided. The circuit includes: (1) a p-type transistor having a first current terminal, a second current terminal, a control terminal, and a bulk terminal, wherein the first current terminal of the p-type transistor is coupled to a first voltage supply; and (2) an n-type transistor having a first current terminal, a second current terminal, a control terminal, and a bulk terminal, wherein the first current terminal of the n-type transistor is coupled to a second voltage supply different from the first voltage supply, wherein the bulk terminal of the p-type transistor, the second current terminal of the p-type transistor, and the control terminal of the n-type transistor is coupled to a first node, wherein the control terminal of the p-type transistor, the bulk terminal of the n-type transistor, and the second current terminal of the second transistor is coupled to a second node different from the first node.

In another aspect, a circuit that may be used as a tie-high/tie-low circuit is provided. The circuit includes: (1) a p-type transistor having a first current terminal, a second current terminal, and a control terminal, wherein the first current terminal of the p-type transistor is coupled to a first voltage supply; and (2) an n-type transistor having a first current terminal, a second current terminal, and a control terminal, wherein the first current terminal of the n-type transistor is coupled to a second voltage supply different from the first voltage supply, wherein the second current terminal of the p-type transistor and the control terminal of the n-type transistor is coupled to a first node, wherein the control terminal of the p-type transistor and the second current terminal of the second transistor is coupled to a second node different from the first node.

In yet another aspect, an integrated circuit including at least one tie circuit is provided. The integrated circuit includes a first voltage terminal for receiving a first voltage supply and as second voltage terminal for receiving a second voltage supply, where the second voltage supply is different from the first voltage supply. The integrated circuit further includes at least one logic portion comprising a plurality of logic gates, wherein a first of the plurality of logic gates is configured to receive a first output value and wherein a second of the plurality of logic gates is configured to receive a second output value. The integrated circuit further includes at least one tie circuit comprising a first output terminal and a second output terminal, wherein the first output terminal is coupled to provide the first output value and the second output terminal is coupled to provide the second output value and wherein the at least one tie circuit is further coupled to receive the first voltage supply and the second voltage supply. The tie circuit includes: (1) a p-type transistor having a first current terminal, a second current terminal, a control terminal, and a bulk terminal, wherein the first current terminal of the p-type transistor is coupled to the first voltage supply; and (2) an n-type transistor having a first current terminal, a second current terminal, a control terminal, and a bulk terminal, wherein the first current terminal of the n-type transistor is coupled to the second voltage supply, wherein the bulk terminal of the p-type transistor, the second current terminal of the p-type transistor, and the control terminal of the n-type transistor is coupled to the first output terminal, wherein the control terminal of the p-type transistor, the bulk terminal of the n-type transistor, and the second current terminal of the second transistor is coupled to the second output terminal.

The terms “assert” or “set” and “negate” (or “deassert” or “clear”) when used herein, refer to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Each signal described herein may be designed as positive or negative logic, where negative logic can be indicated by a bar over the signal name or an asterix (*) following the name. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

FIG. 1 shows an exemplary block diagram of a device 10 including a tie-high/tie-low circuit. Device 10 may include several portions, which may be separate systems, sub-systems, integrated circuits, or other types of components that make up device 10. As used herein, the term “device” includes not only semiconductor devices, but also other types of devices that may include a tie-high/tie-low circuit. By way of example, device 10 may include a portion 12. Portion 12 may be a die, part of a die, or another component that has logic inputs that can be coupled to voltage supply terminals 14 and 16, for example. Voltage supply terminals 14 and 16 may be pads that are used to couple appropriate voltage supplies to device 10. In one embodiment, portion 12 may further include logic portion 18, a logic gate 20, and a tie-high/tie-low circuit 22. By way of example, using conductors 21, voltage VDD may be coupled via voltage supply terminal 16 to tie-high/tie-low circuit 22 and ground voltage VSS may be coupled via voltage supply terminal 14 to tie-high/tie-low circuit 22.

Referring still to FIG. 1, tie-high/tie-low circuit 22 may provide a logic HIGH output and a logic LOW output. Any of these logic values may be coupled to an appropriate logic gate. For example, FIG. 1 shows the logic HIGH value coupled to an input of logic gate 20. Since logic gate 20 is coupled to voltage supply terminal 16 via tie-high/tie-low circuit 22, logic gate 20 is protected in case there is an electrostatic discharge event on voltage supply terminal 16.

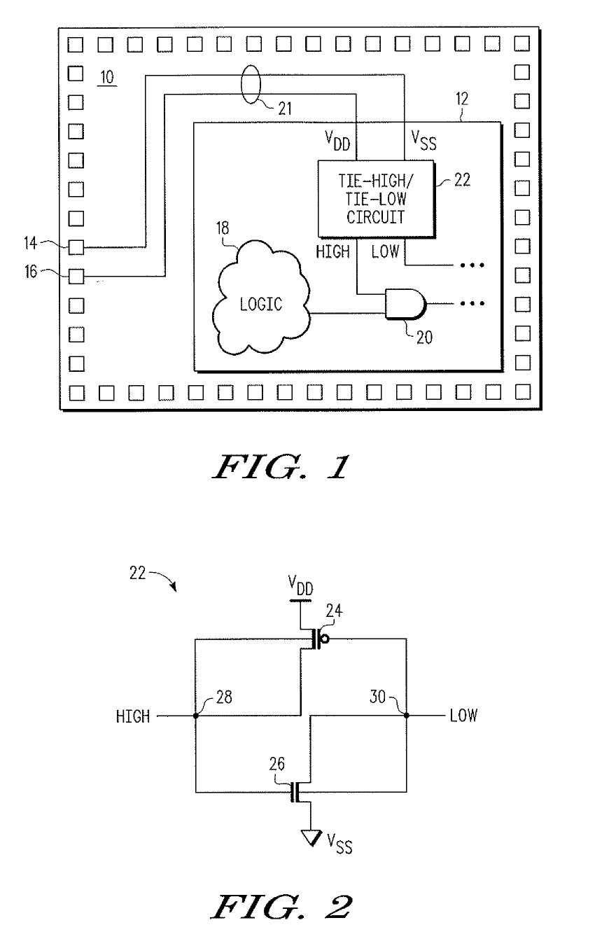

FIG. 2 shows an exemplary circuit diagram of the tie-high/tie-low circuit 22 of FIG. 1. Tie-high/tie-low circuit 22 may include a p-type transistor 24 and an n-type transistor 26. P-type transistor 24 may have a current terminal coupled to voltage VDD. N-type transistor 26 may have a current terminal coupled to ground voltage VSS. Accordingly, in this embodiment, voltage VDD supplies current to at least portion 12 of device 10 and voltage VSS drains current from at least portion 12 of device 10. Voltage VDD may be any appropriate amount of voltage, such as 1.5 Volts, 3 Volts, 5 Volts, or higher. Voltage VSS may be ground voltage, which may be substantially zero voltage or other appropriate amount of voltage.

Furthermore, a bulk terminal and a current terminal of p-type transistor 24 and a control terminal of n-type transistor 26 may be coupled to node 28 providing a logic HIGH value. A bulk terminal and a current terminal of n-type transistor 26 and a control terminal of p-type transistor 24 may be coupled to node 30 providing a logic LOW value. In operation, the coupling of the bulk terminal of p-type transistor 24 to the current terminal of p-type transistor 24 results in body biasing of p-type transistor 24. Similarly, the coupling of the bulk terminal of n-type transistor 26 to the current terminal of n-type transistor 26 results in body biasing of n-type transistor 26. This arrangement relies on leakage currents flowing through the two transistors. The leakage currents are typically the result of short-channel effect and thus tend to worsen with technology scaling. In the embodiment shown in FIG. 2, leakage current flowing through p-type transistor 24 may body bias p-type transistor in a range from 0.1 Volts to 0.5 Volts. In operation, drain-junction leakage will charge up the body of n-type transistor 26 and thus increase its body voltage. This would result in sub-threshold leakage current increase, which in turn will help pull nodes 28 and 30 back to their stable states. This, in effect, makes tie-high/tie-low circuit 22 regenerative without the use of extra biasing circuitry. By way of example, tie-high/tie-low circuit 22 may be used with bulk substrate based transistors.

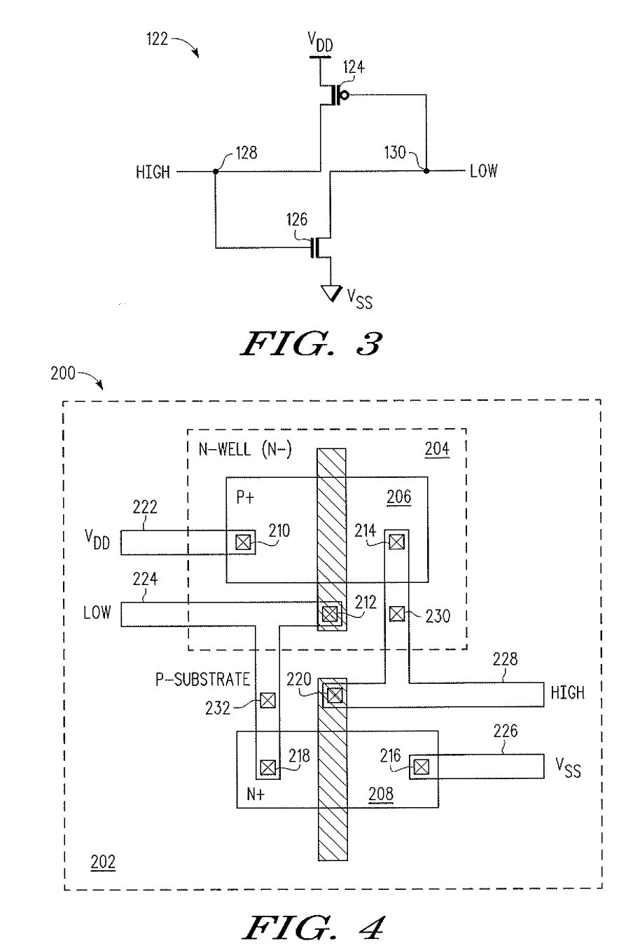

FIG. 3 shows another exemplary circuit diagram of the tie-high/tie-low circuit of FIG. 1. Tie-high/tie-low circuit 122 may include a p-type transistor 124 and an n-type transistor 126. P-type transistor 124 may have a current terminal coupled to voltage VDD. N-type transistor 126 may have a current terminal coupled to ground voltage VSS. Accordingly, in this embodiment, voltage VDD supplies current to at least portion 12 of device 10 and voltage VSS drains current from at least portion 12 of device 10. Voltage VDD may be any appropriate amount of voltage, such as 1.5 Volts, 3 Volts, 5 Volts, or higher. Voltage VSS may be ground voltage.

Furthermore, a current terminal of p-type transistor 124 and a control terminal of n-type transistor 126 may be coupled to node 128 providing a logic HIGH value. A current terminal of n-type transistor 126 and a control terminal of p-type transistor 124 may be coupled to node 130 providing a logic LOW value. By way of example, tie-high/tie-low circuit 122 may be used with silicon-on-insulator (SOI) based transistors. In operation, drain-junction leakage will charge up the body of n-type transistor 126 and thus increase its body voltage. This would result in sub-threshold leakage current increase, which in turn will help pull nodes 128 and 130 back to their stable states.

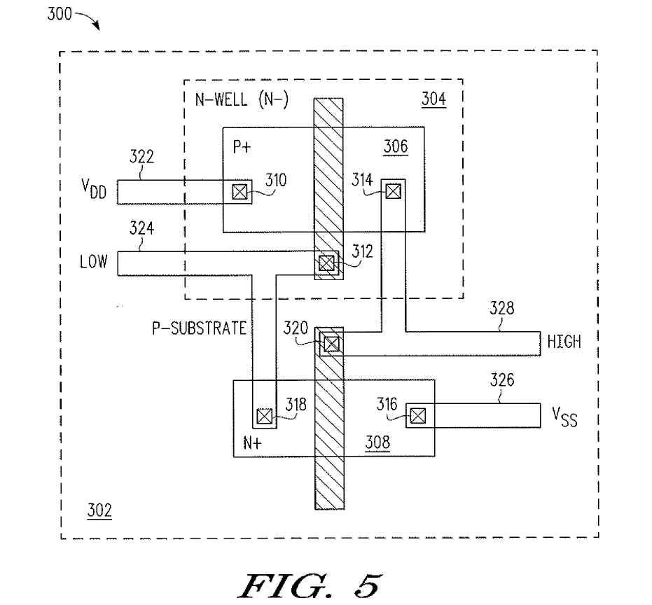

FIG. 4 shows an exemplary layout 200 for tie-high/tie-low circuit 22 of FIG. 2, which may be included as part of portion 202, which in turn may be part of a layout for an integrated circuit. By way of example, the two transistors corresponding to tie-high/tie-low circuit 22 of FIG. 2 may be laid out in the manner shown in FIG. 4. Layout 200 shows an N-WELL region 204 (having a lower concentration of n-type dopants) formed in a P-SUBSTRATE. Layout 200 corresponding to p-type transistor 24 is shown as having P+ region with two contacts 210 and 214. Contact 210 is used to couple a terminal 222 that can be coupled to voltage VDD. Contact 214 is used to couple the P+ region to N-WELL region 204. Layout 200 further shows contact 212 for coupling a terminal 224 to logic LOW value to a gate electrode (which may also be referred to as the control terminal) of p-type transistor 24. Layout 200 further shows an N+region 208 (having a higher concentration of n-type dopants) corresponding to n-type transistor 26. The N+ region is further shown as having a contact 218 coupling N+ region 208 to P-SUBSTRATE via contact 232. Layout 200 further shows contact 220 for coupling a gate electrode (which may also be referred to as the control terminal) of n-type transistor 26 to logic HIGH value using terminal 228. Layout 200 is also shows contact 216 coupling N+ region 208 to ground voltage VSS using terminal 226. Although FIG. 4 shows a specific layout corresponding to tie-high/tie-low circuit 22, tie-high/tie-low circuit 22 may be laid out differently. In addition, other types of doping regions and materials may be used to build tie-high/tie-low circuit 22 using layout 200.

FIG. 5 shows an exemplary layout 300 for the tie-high/tie-low circuit of FIG. 3 which may be included as part of portion 202, which in turn may be part of a layout for an integrated circuit. By way of example, the two transistors corresponding to tie-high/tie-low circuit 122 of FIG. 3 may be laid out in the manner shown in FIG. 5. Layout 300 shows an N-WELL region 304 (having a lower concentration of n-type dopants) formed in a P-SUBSTRATE. Layout 300 corresponding to p-type transistor 124 is shown as having P+ region with two contacts 310 and 314. Contact 310 is used to couple a terminal 322 that can be coupled to voltage VDD. Contact 314 is used to couple the P+ region to N-WELL region 304. Layout 300 further shows contact 312 for coupling a terminal 324 to logic LOW value to a gate electrode (which may also be referred to as the control terminal) of p-type transistor 24. Layout 300 further shows an N+ region 308 (having a higher concentration of n-type dopants) corresponding to n-type transistor 126. Layout 300 further shows contact 320 for coupling a gate electrode (which may also be referred to as the control terminal) of n-type transistor 126 to logic HIGH value using terminal 328. Layout 300 also shows contact 316 coupling N+ region 308 to ground voltage VSS using terminal 326. Although FIG. 5 shows a specific layout corresponding to tie-high/tie-low circuit 122, tie-high/tie-low circuit 122 may be laid out differently. In addition, other types of doping regions and materials may be used to build tie-high/tie-low circuit 122 using layout 300.

Because the apparatus implementing the present invention is, for the most part, composed of electronic components and circuits may be known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans appreciated that conductivity types and polarities of potentials may be reversed.

It is to be understood that the various block diagram implementations depicted herein are merely exemplary, and that in fact many other variations can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the functionality of the above described operations merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A circuit comprising:
a p-type transistor having a first current terminal, a second current terminal, a control terminal, and a bulk terminal, wherein the first current terminal of the p-type transistor is coupled to a first voltage supply; and
an n-type transistor having a first current terminal, a second current terminal, a control terminal, and a bulk terminal, wherein the first current terminal of the n-type transistor is coupled to a second voltage supply different from the first voltage supply, wherein the bulk terminal of the p-type transistor, the second current terminal of the p-type transistor, and the control terminal of the n-type transistor is coupled to a first node, wherein the control terminal of the p-type transistor, the bulk terminal of the n-type transistor, and the second current terminal of the second transistor is coupled to a second node different from the first node.

2. The circuit of claim 1, wherein the first voltage supply is configured to supply a current to the circuit.

3. The circuit of claim 2, wherein the second voltage supply is configured to drain the current from the circuit.

4. The circuit of claim 1, wherein the first node corresponds to a logic high input to at least one logic device and wherein the second node corresponds to a logic low input to at least one logic device.

5. The circuit of claim 1, wherein the bulk terminal of the p-type transistor is coupled to the second current terminal of the p-type transistor to body bias the p-type transistor.

6. The circuit of claim 1, wherein the bulk terminal of the n-type transistor is coupled to the second current terminal of the n-type transistor to body bias the n-type transistor.

7. The circuit of claim 1, wherein the circuit is configured to be regenerative as a result of a leakage current flowing from the first current terminal of the p-type transistor to the second current terminal of the p-type transistor.

8. A circuit comprising:
a p-type transistor having a first current terminal, a second current terminal, and a control terminal, wherein the first current terminal of the p-type transistor is coupled to a first voltage supply; and
an n-type transistor having a first current terminal, a second current terminal, and a control terminal, wherein the first current terminal of the n-type transistor is coupled to a second voltage supply different from the first voltage supply, wherein the second current terminal of the p-type transistor and the control terminal of the n-type transistor is coupled to a first node, wherein the control terminal of the p-type transistor and the second current terminal of the second transistor is coupled to a second node different from the first node.

9. The circuit of claim 8, wherein the first voltage supply is configured to supply a current to the circuit.

10. The circuit of claim 9, wherein the second voltage supply is configured to drain the current from the circuit.

11. The circuit of claim 8, wherein the first node corresponds to a logic high input to at least one logic device and wherein the second node corresponds to a logic low input to at least one logic device.

12. The circuit of claim 8, wherein the circuit is implemented using silicon-on-insulator technology.

13. The circuit of claim 8, wherein the circuit is configured to be regenerative as a result of a leakage current flowing from the first current terminal of the p-type transistor to the second current terminal of the p-type transistor.

14. An integrated circuit comprising:
a first voltage terminal for receiving a first voltage supply;
a second voltage terminal for receiving a second voltage supply, wherein the second voltage supply is different from the first voltage supply;
at least one logic portion comprising a plurality of logic gates, wherein a first of the plurality of logic gates is configured to receive a first output value and wherein a second of the plurality of logic gates is configured to receive a second output value; and
at least one tie circuit comprising a first output terminal and a second output terminal, wherein the first output terminal is coupled to provide the first output value and the second output terminal is coupled to provide the second output value and wherein the at least one tie circuit is further coupled to receive the first voltage supply and the second voltage supply, wherein the at least one tie circuit comprises:
a p-type transistor having a first current terminal, a second current terminal, a control terminal, and a bulk terminal, wherein the first current terminal of the p-type transistor is coupled to the first voltage supply; and
an n-type transistor having a first current terminal, a second current terminal, a control terminal, and a bulk terminal, wherein the first current terminal of the n-type transistor is coupled to the second voltage supply, wherein the bulk terminal of the p-type transistor, the second current terminal of the p-type transistor, and the control terminal of the n-type transistor is coupled to the first output terminal, wherein the control terminal of the p-type transistor, the bulk terminal of the n-type transistor, and the second current terminal of the second transistor is coupled to the second output terminal.

15. The circuit of claim 14, wherein the first voltage supply is configured to supply a current to the circuit.

16. The circuit of claim 15, wherein the second voltage supply is configured to drain the current from the circuit.

17. The circuit of claim 14, wherein the bulk terminal of the p-type transistor is coupled to the second current terminal of the p-type transistor to body bias the p-type transistor.

18. The circuit of claim 14, wherein the bulk terminal of the n-type transistor is coupled to the second current terminal of the n-type transistor to body bias the n-type transistor.

19. The circuit of claim 1, wherein the circuit is configured to be regenerative as a result of a leakage current flowing from the first current terminal of the p-type transistor to the second current terminal of the p-type transistor.

20. The circuit of claim 1, wherein the first voltage supply terminal is an external pad corresponding to the integrated circuit and wherein the second voltage supply terminal is an external pad corresponding to the integrated circuit.
